(19) United States
(12) Patent Application Publication
(10) Pub. No.: US 2025/0043409 A1
(43) Pub. Date: Feb. 6, 2025

(54) DEPOSITION APPARATUS

(71) Applicant: Samsung Display Co., Ltd., Yongin-si (KR)

(72) Inventors: DONGKIUN SEO, Yongin-si (KR); MIN-GYU SEO, Yongin-si (KR); SANGMIN JUNG, Yongin-si (KR); GANYOUNG PARK, Yongin-si (KR); CHULHWAN AN, Yongin-si (KR); HWAPYEONG JEONG, Yongin-si (KR)

(73) Assignee: Samsung Display Co., Ltd., Yongin-si (KR)

(21) Appl. No.: 18/654,289

(22) Filed: May 3, 2024

(30) Foreign Application Priority Data
Aug. 1, 2023 (KR) 10-2023-0100351

(51) Int. Cl. C23C 14/24; C23C 14/04; H10K 59/12; H10K 71/16

(52) U.S. Cl. CPC C23C 14/243; C23C 14/042; H10K 59/12; H10K 71/166

(57) ABSTRACT

A deposition apparatus includes a mask frame, a mask disposed on the mask frame, a crucible disposed below the mask frame, and a nozzle coupled to the crucible, and disposed between the crucible and the mask frame. The nozzle includes a body part including a coupling opening, and a spray part disposed in the coupling opening and including a hole overlapping the coupling opening. A thermal expansion coefficient of the spray part is greater than a thermal expansion coefficient of the body part.

### CROSS-REFERENCE TO RELATED APPLICATION(S)

This application claims priority to and benefits of Korean Patent Application No. 10-2023-0100351 under 35 U.S.C. § 119, filed on Aug. 1, 2023, the entire contents of which are incorporated herein by reference.

### BACKGROUND

### 1. Technical Field

Embodiments relate to a deposition apparatus.

### 2. Description of the Related Art

Organic light emitting diode display (OLED) devices, which have excellent luminance characteristics and wide viewing angle characteristics and do not require a separate light source unlike liquid crystal display (LCD) devices, are getting attention as next-generation flat panel display devices. The OLED devices do not require a separate light source, and may thus be manufactured to have a lightweight and a slim design. Also, the OLED devices have characteristics of low power consumption, high luminance, and fast response speed.

The OLED devices include organic light emitting elements each including an anode, an organic light emitting layer, and a cathode. Holes and electrons are injected into the organic light emitting layer from the anode and the cathode respectively, to generate excitons, and the organic light emitting element emits light as the excitons transition to the ground state.

In case that organic light emitting elements are manufactured, a mask is placed on a substrate an organic material for forming organic light emitting layers through an open portion of the mask from a nozzle, and provided on the substrate.

### SUMMARY

Embodiments provide a deposition apparatus including a nozzle with a spray part, a body part, which is formed of a material different from that of the spray part, and a coupling member, which is separable and replaceable from the body part.

However, embodiments are not limited to those set forth herein. The above and other embodiments will become more apparent to one of ordinary skill in the art to which the disclosure pertains by referencing the detailed description of the disclosure given below.

In an embodiment, a deposition apparatus may include a mask frame, a mask disposed on the mask frame, a crucible disposed below the mask frame and a nozzle disposed between the crucible and the mask frame and coupled to the crucible, wherein the nozzle includes a body part including a coupling opening, and a spray part disposed in the coupling opening and include a hole overlapping the coupling opening, and a thermal expansion coefficient of the spray part may be greater than a thermal expansion coefficient of the body part.

The crucible and the body part may include a same material, and the spray part may include a material different from materials of the crucible and the body part.

The body part may further include body protrusions disposed in the coupling opening and disposed on an inner surface of the body part, the spray part may further include coupling protrusions disposed on an outer surface of the spray part, the body protrusions and the coupling protrusions may be coupled to each other, and the body part and the spray part may be coupled to each other in an engaged manner by the body protrusions and the coupling protrusions.

The nozzle may further include a coupling member disposed in the coupling opening and including a spray hole, and the body part and the spray part may be coupled to each other by the coupling member.

A thermal expansion coefficient of the coupling member may be smaller than the thermal expansion coefficient of the spray part.

The coupling opening of the body part may include: a first coupling opening adjacent to an upper surface of the body part; and a second coupling opening disposed below the first coupling opening and having a diameter larger than a diameter of the first coupling opening.

The coupling member may include first spray protrusions disposed on an inner surface of the coupling member and disposed in the spray hole, the spray part may include coupling protrusions disposed on an outer surface of the spray part, the coupling member may be disposed in the second coupling opening of the body part, and the coupling protrusions may be coupled to the first spray protrusions in an engaged manner such that the spray part and the coupling member are coupled to each other.

The coupling member may further include second spray protrusions disposed on an outer surface of the coupling member.

The body part may include body protrusions disposed on an inner surface of the body part and disposed in the second coupling opening, and the body protrusions may include coupled to the second spray protrusions of the coupling member in an engaged manner such that the body part and the coupling member are coupled to each other.

The coupling opening of the body part may include: a first coupling opening adjacent to an upper surface of the body part; a second coupling opening disposed below the first coupling opening; and a third coupling opening disposed below the second coupling opening, the first coupling opening has a larger diameter than the second coupling opening, and the third coupling opening has a larger diameter than the second coupling opening.

The coupling member may include: a first part having a cylindrical shape; a second part disposed on the first part and having, in plan, a cylindrical shape having a diameter smaller than a diameter of the first part; and a spray protrusion disposed on an outer surface of the second part, the first part is disposed in the first coupling opening of the body part, and the second part is disposed in the second coupling opening of the body part.

The spray part may include: a first spray part having a cylindrical shape; a second spray part disposed on the first spray part and having, in plan view, a cylindrical shape having a diameter smaller than a diameter of the first spray part; and a coupling protrusion disposed on an inner surface of the first spray part and disposed in the hole of the spray part, and the coupling protrusion may be coupled to the spray protrusion of the coupling member in an engaged manner within the second coupling opening such that the spray part and the coupling member are coupled to each other.

The spray part may further include a support part disposed between the first spray part and the second spray part and having a ring shape, and the support part may be disposed in the third coupling opening of the body part.

An upper surface of the spray part may have a ring shape in plan view, and a plurality of fastening grooves may be formed in an outer surface of the spray part.

An upper surface of the spray part may have a polygonal shape in plan view, and an outer surface of the spray part may include a plurality of flat surfaces.

In an embodiment, a deposition apparatus may include a mask frame, a mask disposed on the mask frame, a crucible disposed below the mask frame and a nozzle disposed between the crucible and the mask frame, wherein the nozzle includes a body part including a coupling opening, a spray part disposed in the coupling opening and including a hole overlapping the coupling opening, and a coupling member disposed between the body part and the spray part, and including a spray hole, and the body part and the spray part may be coupled to each other by the coupling member.

The spray part may include a coupling protrusion disposed on an outer surface of the spray part, the coupling member may include a first spray protrusion disposed on an inner surface of the coupling member and disposed in the spray hole, and the first spray protrusion and the coupling protrusion may be coupled to each other in an engaged manner.

The body part may include a body protrusion disposed on an inner surface of the body part and disposed in the coupling opening, the coupling member may further include a second spray protrusion disposed on an outer surface of the coupling member, and the second spray protrusion and the body protrusion may be coupled to each other in an engaged manner.

The coupling member may include: a first part having a cylindrical shape; a second part disposed on the first part; and a spray protrusion disposed on an outer surface of the second part.

The spray part may include a coupling protrusion disposed on an inner surface of the spray part and disposed in the hole of the spray part, and the coupling protrusion and the spray protrusion may be coupled to each other in an engaged manner.

### BRIEF DESCRIPTION OF THE DRAWINGS

The accompanying drawings are included to provide a further understanding of the invention and are incorporated in and constitute a part of the disclosure. The drawings illustrate embodiments and, together with the description, serve to explain principles of the invention. In the drawings:

FIG. 1 is a schematic perspective view of a deposition apparatus according to an embodiment;

FIG. 2 is an exploded schematic perspective view of a nozzle NZ illustrated in FIG. 1;

FIGS. 3A and 3B are schematic diagrams illustrating a coupling of a spray part and a body part illustrated in FIG. 2;

FIGS. 4A and 4B are schematic diagrams illustrating a nozzle according to another embodiment;

FIGS. 5A and 5B are schematic diagrams illustrating a nozzle according to another embodiment;

FIGS. 6A and 6B are schematic diagrams illustrating a nozzle according to another embodiment;

FIGS. 7A and 7B are schematic diagrams illustrating a spray part according to another embodiment;

FIG. 8 is a schematic plan view of a display panel manufactured using the deposition apparatus illustrated in FIG. 1;

FIG. 9 is a schematic diagram illustrating a cross-section of a pixel illustrated in FIG. 8; and

FIG. 10 is a schematic diagram illustrating a deposition process for a light emitting element illustrated in FIG. 9.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Embodiments described herein will be illustrated with reference to a plan view and a cross-sectional view, which are ideal schematic views of the embodiment. Therefore, the shape of the illustration may be deformed by manufacturing technology and/or tolerance. Accordingly, embodiments are not limited to the illustrated specific forms but include changes in forms generated according to the manufacturing process. Therefore, the areas in the drawings have schematic properties, and the shape of the areas in the drawings illustrates a specific form of the area of the element and is not to limit the category of invention.

Hereinafter, embodiments will be described in detail with reference to the accompanying drawings.

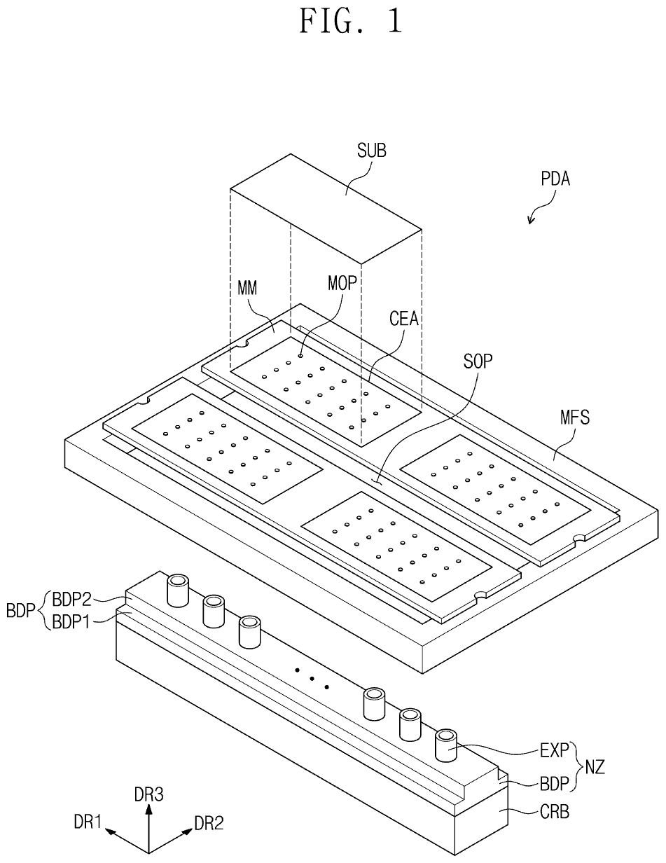

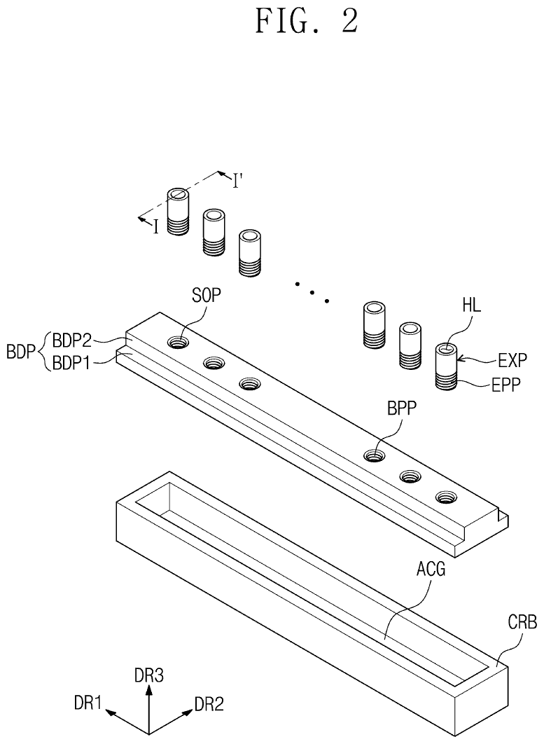

FIG. 1 is a schematic perspective view of a deposition apparatus according to an embodiment. FIG. 2 is an exploded schematic perspective view of a nozzle NZ illustrated in FIG. 1.

Referring to FIG. 1, a deposition apparatus PDA may include a mask frame MFS, masks MM, a nozzle NZ, and a crucible CRB.

The mask frame MFS may have side surfaces extending in the first direction DR1 and side surfaces extending in the second direction DR2 crossing the first direction DR1. The mask frame MFS may have a rectangular frame shape, but the shape of the mask frame MFS is not limited thereto.

Hereinafter, a direction crossing a plane defined by the first direction DR1 and the second direction DR2 is defined as a third direction DR3. The third direction DR3 may be substantially orthogonal to a plane defined by the first direction DR1 and the second direction DR2. In the disclosure, “in plan view” may mean a state of being viewed in the third direction DR3.

In plan view, the mask frame MFS may have a quadrilateral shape having long sides extending in the first direction DR1 and short sides extending in the second direction DR2.

A mask opening MK-OP may be defined (or formed) in the mask frame MFS. The mask opening MK-OP may have a quadrilateral shape, but the shape of the mask opening MK-OP is not limited thereto.

The mask frame MFS may include a metallic material. For example, the mask frame MFS may include invar or stainless steel.

On the mask frame MFS, masks MM may be disposed. Sides (e.g., opposite sides) of the masks MM, which are opposite to each other in the first direction DR1, may be connected to the mask frame MFS. For example, the masks MM may be connected to the mask frame MFS by laser welding.

The masks MM may extend in the first direction DR1 and arranged in the second direction DR2. The masks MM may have a rectangular shape having long sides in the first direction DR1 and short sides in the second direction DR2. For example, two masks MM may be disposed on the mask frame MFS, but the number of the masks MM is not limited thereto.

The masks MM may include metal. For example, the masks MM may be defined as a fine metal mask.

Cell regions CEA may be defined on an upper surface of each of the masks MM. Although two cell regions CEA are defined on the upper surface of each of the mask MM, the number of cell regions CEA is not limited thereto.

The cell regions CEA may be arranged in a certain direction. The cell regions CEA may be arranged in the first direction. In plan view, the cell regions CEA may overlap the mask opening MK-OP. In plan view, the cell regions CEA may not overlap the mask frame MFS.

The cell regions CEA may have a polygonal shape. For example, each of the cell regions CEA may have a rectangular shape having long sides in the first direction DR1 and short sides in the second direction DR2.

Cell openings MOP may be defined (or formed) in the cell regions CEA. The cell openings MOP may be arranged in the first direction DR1 or the second direction DR2. In plan view, the cell openings MOP may overlap the mask opening MK-OP.

For example, twenty cell openings MOP may be defined (or formed) in each of the cell regions CEA, but the number of the cell openings may not be limited thereto.

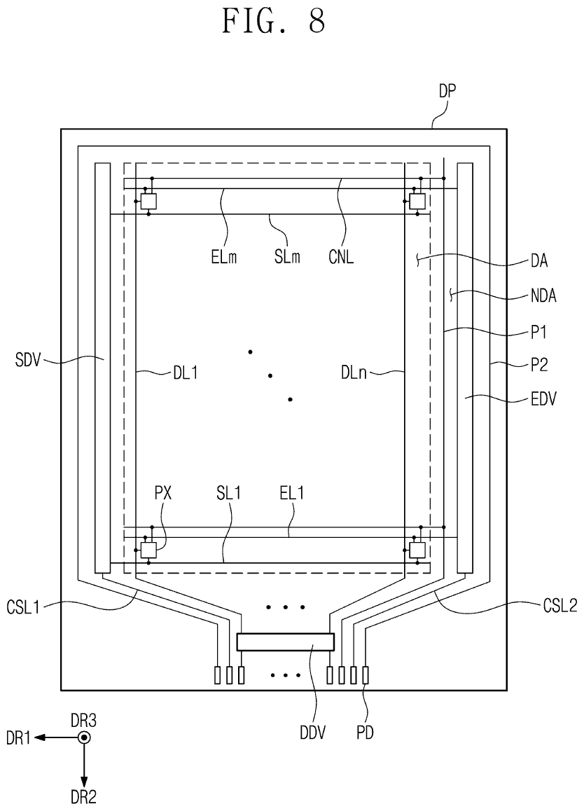

A substrate SUB may be disposed on the cell regions CEA. In case that a deposition material is sprayed from a nozzle to be described later, the deposition material may be deposited in a region overlapping the cell openings MOP of the substrate SUB. Deposition of the deposition material will be described in detail with reference to FIGS. 8, 9, and 10.

Referring to FIGS. 1 and 2, a crucible CRB may be disposed below the mask frame MFS. The crucible CRB may have a rectangular parallelepiped shape. The crucible CRB may include surfaces extending in the first direction DR1 and surfaces extending in the second direction DR2. In plan view, the crucible CRB may have a rectangular shape having long sides extending in the first direction DR1 and short sides extending in the second direction DR2.

An accommodation groove ACT may be defined (or formed) in the crucible CRB. The accommodation groove ACG may extend from the top to the bottom. In plan view, the accommodation groove ACG may have a rectangular shape.

The crucible CRB may accommodate a deposition material therein. The deposition material may be accommodated in the accommodation groove ACG of the crucible CRB. For example, heating lines capable of heating the deposition material may be included. Accordingly, in case that the deposition material is provided to the accommodation groove ACG, the deposition material may be evaporated (or vaporized) by the heating lines of the crucible CRB.

The crucible CRB may include metallic or non-metallic materials. For example, the crucible CRB may include any one of molybdenum (Mo), tungsten, Mo—La, which is an alloy of molybdenum and lanthanum oxide (La₂O₃), tantalum (Ta), a carbon composite, and titanium-zirconium molybdenum (TZM) in which titanium, carbon, and zirconium are added to molybdenum. However, embodiments are not limited thereto, and the crucible CRB may include another material of which the melting point is higher than the boiling point of the deposition material.

A nozzle NZ may be disposed between the crucible CRB and the mask frame MFS. The nozzle NZ may be disposed on the crucible CRB. The nozzle NZ may overlap the accommodation groove ACG defined (or formed) in the crucible CRB.

In plan view, the nozzle NZ may have a rectangular shape having long sides extending in the first direction DR1 and short sides extending in the second direction DR2.

The nozzle NZ may include a body part BDP and a spray part EXP. The spray part EXP may be disposed on the body part BDP.

The body part BDP may include a first body part BDP1 and a second body part BDP2. The first body part BDP1 may be disposed on an upper surface of the crucible CRB. The second body part BDP2 may be disposed on an upper surface of the first body part BDP1. The second body part BDP2 may extend from the first body part BDP1 in the third direction DR3. For example, the first body part BDP1 and the second body part BDP2 may be integral with each other.

A length of the first body part BDP1 in the first direction DR1 and a length of the second body part BDP2 in the first direction DR1 may be substantially equal to each other. A length (or width) of the first body part BDP1 in the second direction DR2 may be greater than a length (or width) of the second body part BDP2 in the second direction DR2. Accordingly, the first body part BDP1 and the second body part BDP2 may have a stepped portion in the second direction DR2.

The body part BDP and the crucible CRB may include the same material. The body part BDP may include metallic or non-metallic materials. For example, the body part BDP may include any one of molybdenum (Mo), tungsten, Mo—La, which is an alloy of molybdenum and lanthanum oxide (La₂O₃), tantalum (Ta), a carbon composite, and titanium-zirconium molybdenum (TZM) in which titanium, carbon, and zirconium are added to molybdenum. However, embodiments are not limited thereto, and the body part BDP may include another material of which the melting point is higher than the boiling point of the deposition material. Since the body part BDP and the crucible CRB include the same material, the thermal expansion rate of the body part BDP and the thermal expansion rate of the crucible CRB may be the same in case that the deposition material is heated to be vaporized (or evaporated). The thermal expansion amount of the body part BDP and the thermal expansion amount of the crucible CRB may be the same. Accordingly, a gap may not occur between the body part BDP and the crucible CRB. Therefore, in case that heat is applied, the space between the body part BDP and the crucible CRB may be sealed, and the deposition material may not leak between the body part BDP and the crucible CRB.

In an upper surface of the second body part BDP2, coupling openings SOP may be defined (or formed). The coupling openings SOP may be arranged along the first direction DR1. The coupling openings SOP may be spaced apart from each other at certain intervals in the first direction DR1. In plan view, each of the coupling openings SOP may have a circular shape.

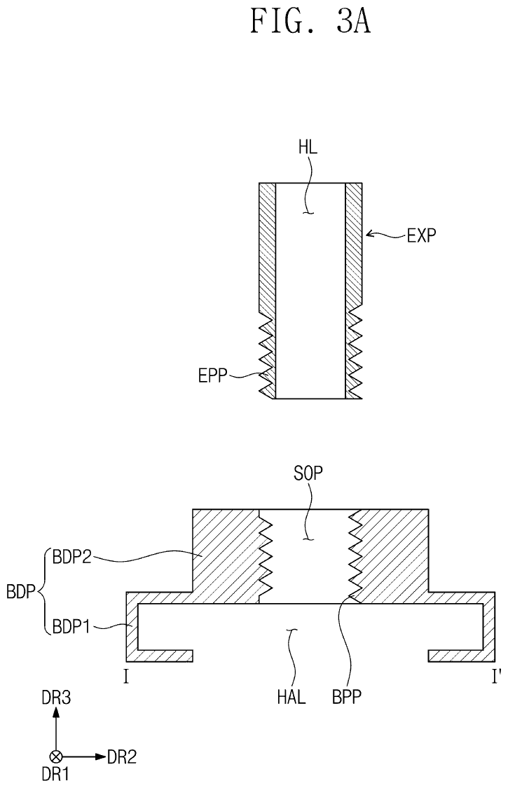

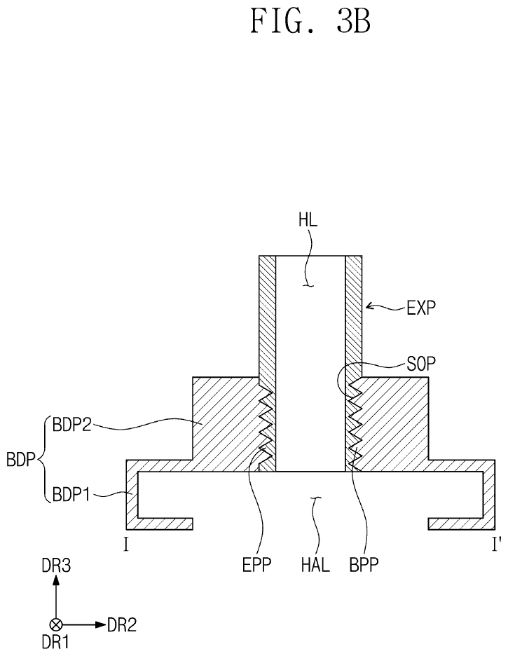

The spray parts EXP may be detachably coupled to the body part BDP. The spray parts EXP may be disposed (or inserted) in the coupling openings SOP defined (or formed) in the second body part BDP2. This will be described in detail with reference to FIGS. 3A, 3B, 4A, 4B, 5A, 5B, 6A, and 6B.

The spray parts EXP may include metallic or non-metallic materials. On the condition that the thermal expansion coefficient of the spray parts EXP is greater than the thermal expansion coefficient of the body part BDP, the spray parts EXP and the body part BDP may include different materials. Accordingly, in case that the deposition material is heated, the spray parts EXP may expand within the coupling openings SOP. Therefore, the space between the spray parts EXP and the body part BDP may be sealed.

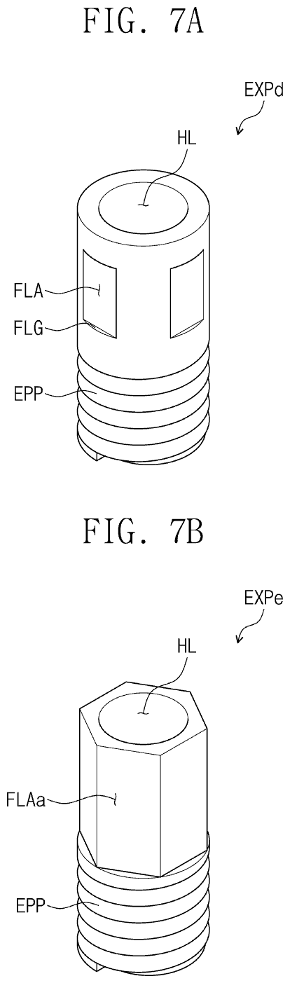

For example, the spray parts EXP may have a cylindrical shape. However, embodiments are not limited thereto, and flat surfaces may be disposed on an outer surface of the spray parts EXP. This will be described in detail with reference to FIGS. 7A and 7B.

Holes HL may be defined (or formed) in an upper space of the spray parts EXP. The holes HL may extend in the third direction DR3. The holes HL may overlap the coupling openings SOP and the accommodation groove ACG. Therefore, the deposition material disposed in the accommodation groove ACG may be vaporized (or evaporated) and sprayed to the masks MM through the holes HL.

The spray parts EXP may further include coupling protrusions EPP. The coupling protrusions EPP may be disposed on an outer surface of the spray parts EXP. The coupling protrusions EPP may be disposed adjacent to the lower portion of the spray parts EXP. The spray parts EXP may be coupled to the body part BDP by the coupling protrusions EPP. This will be described in detail with reference to FIGS. 3A and 3B.

For example, the deposition apparatus PDA may further include a cooling plate and a magnet plate on the mask frame MFS. The cooling plate may prevent thermal deformation of a display panel DP (see FIG. 8) disposed on the masks MM. The magnet plate may prevent the masks MM and the display panel DP (see FIG. 8) from sagging downwards due to gravity.

FIGS. 3A and 3B are schematic diagrams illustrating coupling of the spray part and the body part illustrated in FIG. 2.

For example, FIG. 3A illustrates a state in which the spray part EXP and the body part BDP are separated. FIG. 3B illustrates a state in which the spray part EXP and the body part BDP are coupled.

For example, FIGS. 3A and 3B are cross-sectional views taken along line I-I′ in FIG. 2.

For convenience of explanation, the crucible CRB (see FIG. 1), the mask frame MFS (see FIG. 1), and the masks MM (see FIG. 1) are omitted in FIGS. 3A and 3B.

The spray part EXP and the body part BDP in FIGS. 3A and 3B are the same as the spray part EXP and the body part BDP in FIGS. 1 and 2, and thus descriptions thereof will be omitted or simplified for descriptive convenience.

Referring to FIG. 3A, the coupling protrusions EPP may be disposed on the outer surface of the spray part EXP. The hole HL may be defined (or formed) in the spray part EXP. The hole HL may extend in the third direction DR3 from an upper surface to a lower surface of the spray part EXP.

A connection groove HAL may be defined by (or formed in) the first body part BDP1. The connection groove HAL may overlap the accommodation groove ACG of the crucible CRB illustrated in FIG. 2.

A coupling opening SOP may be defined (or formed) in the body part BDP. The coupling opening SOP may extend from an upper surface of the second body part BDP2 toward the third direction DR3. The coupling opening SOP may be connected to the connection groove HAL.

The body part BDP may further include body protrusions BPP. The body protrusions BPP may be disposed in the coupling openings SOP. The body protrusions BPP may be disposed on the inner surface of the second body part BDP2 that defines the coupling opening SOP. When viewed from the first direction DR1, the body protrusions BPP may be arranged in the third direction DR3. However, embodiments are not limited thereto, and the body protrusions BPP may be omitted.

Referring FIGS. 3A and 3B, the spray part EXP may be coupled to the body part BDP. The spray part EXP may be coupled to the second body part BDP2. The spray part EXP may be disposed (or inserted) in the coupling opening SOP.

Coupling protrusions EPP of the spray part EXP may have shapes corresponding to those of the body protrusions BPP of the body part BDP. In case that the spray part EXP is disposed within the coupling opening SOP, the coupling protrusions EPP may be engaged with the body protrusions BPP. The coupling protrusions EPP and the body protrusions BPP may be coupled to each other in an engaged manner. Accordingly, the spray part may be coupled to the body part.

The thermal expansion coefficient of the spray part EXP may be greater than the thermal expansion coefficient of the body part BDP. In case that the deposition material is heated, the thermal expansion amount of the spray part EXP may be greater than the thermal expansion amount of the body part BDP. Accordingly, the spray part EXP may be expanded within the coupling opening SOP, so that the space between an outer surface of the spray part EXP and an inner surface of the body part BDP may be sealed. Therefore, the evaporated deposition material may be sprayed to the outside from the hole HL after passing through the connection groove HAL, and it is thus possible to prevent the deposition material from leaking to a space between the outer surface of the spray part EXP and the inner surface of the body part BDP.

The spray part EXP may include metallic or non-metallic materials. For example, the spray part EXP may include any one of molybdenum (Mo), tungsten, Mo—La, which is an alloy of molybdenum and lanthanum oxide (La₂O₃), tantalum (Ta), a carbon composite, and titanium-zirconium molybdenum (TZM) in which titanium, carbon, and zirconium are added to molybdenum. However, embodiments are not limited thereto, and the spray part EXP may include another material of which the melting point is higher than the boiling point of the deposition material.

On the condition that the thermal expansion coefficient of the spray parts EXP is greater than the thermal expansion coefficient of the body part BDP, the spray parts EXP and the body part BDP may include different materials. For example, the spray part EXP may include a metal and the body part BDP may include a non-metal. However, embodiments are not limited thereto, and the spray part EXP and the body part BDP each may include any metals as long as the thermal expansion coefficient of the spray part EXP is greater than the thermal expansion coefficient of the body part BDP.

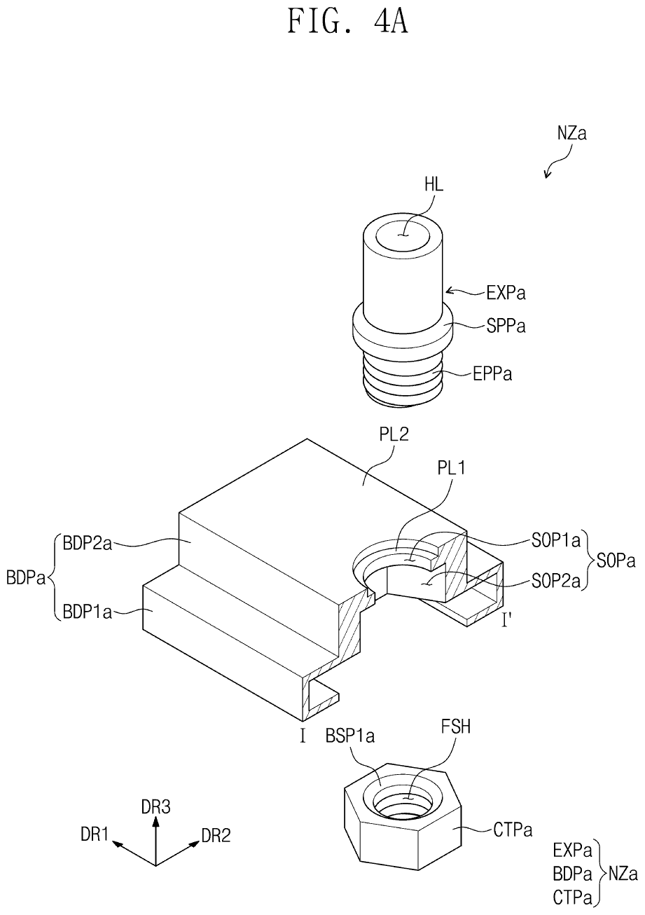

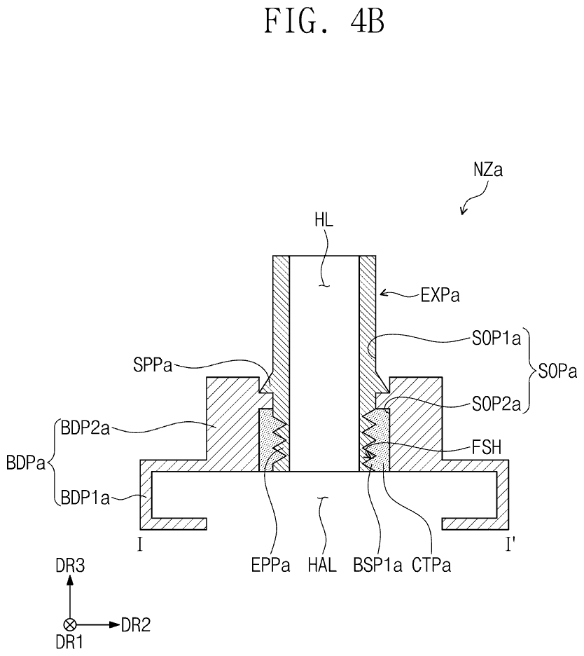

FIGS. 4A and 4B are schematic diagrams illustrating a nozzle according to another embodiment.

For convenience of explanation, in FIG. 4A, a body part BDPa is illustrated in a cross-sectional view taken along line I-I′, and a spray part EXPa and a coupling member CTPa are illustrated in a perspective view.

FIG. 4A is a schematic diagram illustrating the body part BDPa, the spray part EXPa, and the coupling member CTPa which are separated from each other, and FIG. 4B is a schematic diagram illustrating the body part BDPa, the spray part EXPa, and the coupling member CTPa which are coupled to each other.

Since coupling protrusions EPPa of the spray part EXPa illustrated in FIGS. 4A and 4B are substantially the same as the coupling protrusions EPP of the spray part EXP illustrated in FIG. 3A, a description thereof may be omitted or simplified for descriptive convenience.

Referring FIG. 4A, the body part BDPa may include a first body part BDP1a and a second body part BDP2a. An upper surface of the second body part BDP2a may include a stepped portion. A first surface PL1 of the upper surface of the second body part BDP2a, which is adjacent to a coupling opening SOPa, and a second surface PL2 of the upper surface of the second body part BDP2a, which is spaced apart from the coupling opening SOPa, may be connected to form the stepped portion. The height of the first surface PL1 of the upper surface of the second body part BDP2a, which is adjacent to the coupling opening SOPa, may be lower than the height of the second surface PL2 of the upper surface of the second body part BDP2a, which is spaced apart from the coupling opening SOPa.

The coupling opening SOPa may include a first coupling opening SOP1a and a second coupling opening SOP2a. The first coupling opening SOP1a may be adjacent to the upper surface of the second body part BDP2a. The second coupling opening SOP2a may be defined below the first coupling opening SOP1a. The second coupling opening SOP2a may be adjacent to the boundary between the first body part BDP1a and the second body part BDP2.

The maximum diameter (or diameter) of the first coupling opening SOP1a in the second direction DR2 may be smaller than the maximum diameter (or diameter) of the second coupling opening SOP2a in the second direction DR2. Accordingly, an inner surface of the second body part BDP2a defining the coupling openings SOPa may have a stepped shape.

For example, in FIG. 4A, the first coupling opening SOP1a may have a semicircular shape, but may have a substantially circular shape. For example, in FIG. 4A, the second coupling opening SOP2a may have a part of a polygonal shape, but may have a substantially polygonal shape. The inner surface of the second body part BDP2a defining the second coupling opening SOP2a may include flat surfaces. The flat surfaces may be arranged at certain angles.

A nozzle NZa may further include a coupling member CTPa. An upper surface of the coupling member CTPa may have a polygonal shape. The coupling member CTPa may have a polygonal column shape. For example, in FIG. 4A, the coupling member CTPa may have a hexagonal column shape. This is illustrated as an example, and the shape of the coupling member CTPa may be changed to correspond to the shape of the inner surface of the second body part BDP2a defining the second coupling opening SOP2a.

The spray part EXPa may further include a support part SPPa. The support part SPPa may be disposed on the coupling protrusions EPPa. For example, the support part SPPa may have an annular shape. The support part SPPa may surround an outer surface of the spray part EXPa.

A spray hole FSH may be defined (or formed) in the upper surface of the coupling member CTPa. The spray hole FSH may extend in the third direction DR3 and penetrate the coupling member CTPa.

Referring to FIGS. 4A and 4B, the coupling member CTPa, the spray part EXPa, and the body part BDPa may be coupled to each other. For example, the coupling member CTPa may be disposed (or inserted) in the second coupling opening SOP2a. The spray hole FSH may overlap the connection groove HAL. The spray hole FSH may overlap the coupling opening SOPa.

The coupling member CTPa may include first spray protrusions BSP1a. The first spray protrusions BSP1a may be disposed on an inner surface of the coupling member CTPa defining the spray hole FSH. The first spray protrusions BSP1a may be disposed to correspond to the coupling protrusions EPPa of the spray part EXPa.

The spray part EXPa may be disposed (or inserted) in the coupling opening SOPa of the body part BDPa. The spray part EXPa may be disposed (or inserted) in the spray hole FSH of the coupling member CTPa. The coupling protrusions EPPa may be coupled to the first spray protrusions BSP1a in an engaged manner. The spray part EXPa and the coupling member CTPa may be coupled to each other by the coupling protrusions EPPa and the first spray protrusions BSP1a.

The support part SPPa of the spray part EXPa may be disposed on the upper surface of the second body part BDP2a. The support part SPPa may be disposed on the upper surface of the second body part BDP2a adjacent to the coupling opening SOPa. Since the support part SPPa is disposed on the upper surface of the second body part BDP2a, only a portion of the spray part EXPa may be disposed (or inserted) in the coupling opening SOPa.

In case that the spray part EXPa and the body part BDPa are directly connected, wear may occur between the outer surface of the spray part EXPa and the inner surface of the body part BDPa. Accordingly, a gap may be formed between the outer surface of the spray part EXPa and the inner surface of the body part BDPa, and may cause the evaporated deposition material to leak out through the gap. For example, the lifespan of the body part BDPa may be shortened.

However, in case that the spray part EXPa is coupled to the body part BDPa by the coupling member CTPa, wear may not occur on the inner surface of the body part BDPa. Therefore, the lifespan of the body part BDPa may be extended. In case that the spray part EXPa is coupled to the coupling member CTPa, in case that wear occurs on the inner surface of the coupling member CTPa, the coupling member CTPa may be coupled to be detachable from the body part BDPa, so that the coupling member CTPa may be readily replaced. Accordingly, maintenance of the nozzle NZa may be readily performed.

The thermal expansion coefficient of the spray part EXPa may be greater than the thermal expansion coefficient of the coupling member CTPa. In case that the deposition material is heated to be evaporated (or vaporized), the thermal expansion amount of the spray part EXPa may be greater than the thermal expansion amount of the coupling member CTPa. The spray part EXPa may expand within the spray hole FSH. Therefore, the deposition material may not leak to a space between the outer surface of the spray part EXPa and the inner surface of the coupling member BSP1a, and the deposition material may be sprayed to the outside through the hole HL, thereby reducing unnecessary loss of the deposition material.

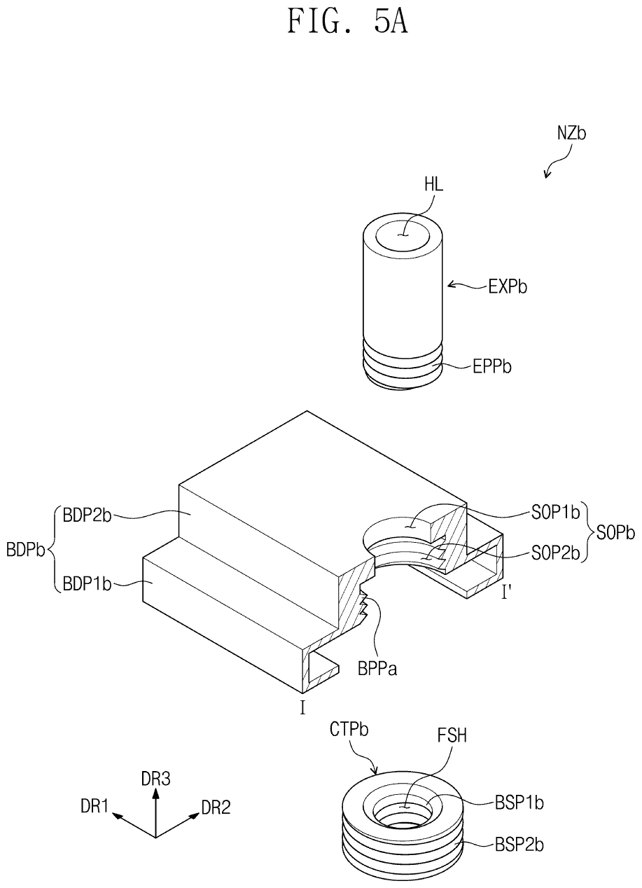

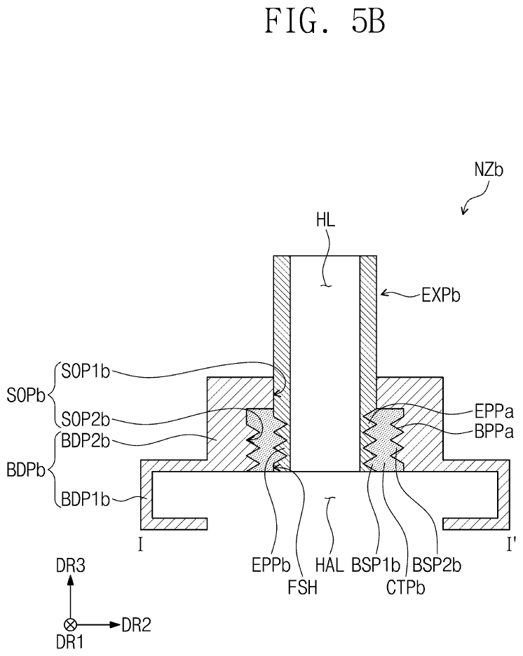

FIGS. 5A and 5B are schematic diagrams illustrating a nozzle according to another embodiment.

For convenience of explanation, in FIG. 5A, a body part BDPb is illustrated in a cross-sectional view taken along line I-I′, and a spray part EXPb and a coupling member CTPb are illustrated in a perspective view.

FIG. 5A illustrates a state in which the body part BDPb, the spray part EXPb, and the coupling member CTPb are separated from each other, and FIG. 5B illustrates a state in which the body part BDPb, the spray part EXPb, and the coupling member CTPb are coupled to each other.

Since the spray part EXPb in FIGS. 5A and 5B is the same as the spray part EXP in FIGS. 3A and 3B, a description thereof will be omitted or simplified for descriptive convenience.

Referring to FIG. 5A, a coupling opening SOPb may include a first coupling opening SOP1b and a second coupling opening SOP2b. The first coupling opening SOP1b may be adjacent to an upper surface of a second body part BDP2b. The second coupling opening SOP2b may defined below the first coupling opening SOP1b. The second coupling opening SOP2b may be adjacent to the boundary between a first body part BDP1b and the second body part BDP2b.

The maximum diameter of the first coupling opening SOP1b in the second direction DR2 may be smaller than the maximum diameter of the second coupling opening SOP2b in the second direction DR2. Accordingly, an inner surface of the second body part BDP2b defining the coupling openings SOPb may have a stepped shape.

The body part BDPb may further include body protrusions BPPa. The body protrusions BPPa may be disposed in the second coupling opening SOP2b.

A nozzle NZb may further include the coupling member CTPb. The coupling member CTPb may have a cylindrical shape. The spray hole FSH may be defined on an upper surface of the coupling member CTPb. The spray hole FSH may extend in the third direction DR3 and penetrate the coupling member CTPb.

The coupling member CTPb may include first spray protrusions BSP1b and second spray protrusions BSP2b. The first spray protrusions BSP1b may be disposed on an inner surface of the coupling member CTPb defining the spray hole FSH. The first spray protrusions BSP1b may be disposed to correspond to the coupling protrusions EPPa of the spray part EXPb. The second spray protrusions BSP2b may be disposed on an outer surface of the coupling member CTPb. The second spray protrusions BSP2b may be disposed to correspond to the body protrusions BPPa.

Referring to FIGS. 5A and 5B, the body part BDPb, the spray part EXPb, and the coupling member CTPb may be coupled to each other. The coupling member CTPb may be disposed in the second coupling opening SOP2b. The second spray protrusions BSP2b of the coupling member CTPb may be coupled to the body protrusions BPPa disposed in the second coupling opening SOP2b in an engaged manner. The coupling member CTPb and the body part BDPb may be coupled to each other by the second spray protrusions BSP2b and the body protrusions BPPa.

The spray part EXPb may be disposed (or inserted) in the coupling opening SOPb. The spray part EXPb may be disposed (or inserted) in the spray hole FSH. The coupling protrusions EPPa of the spray part EXPb may be coupled to the first coupling protrusions BSP1b of the coupling member CTPb in an engaged manner. The coupling protrusions EPPa and the first spray protrusions BSP1b may be coupled to each other in an engaged manner. Accordingly, the spray part EXPb and the coupling member CTPb may be coupled to each other by the coupling protrusions EPPa and the first spray protrusions BSP1b. The spray part EXPb may be coupled to the body part BDPb by the coupling member CTPb.

The possibility of occurrence of wear on an inner surface of the body part BDPb may be reduced in a case where the spray part EXPb is coupled to the body part BDPb by the coupling member CTPb, compared to a case where spray part EXPb and the body part BDPb are directly coupled to each other. Accordingly, the lifespan of the body part BDPb may be extended.

For example, since the coupling member CTPb is coupled to be detachable from the body part BDPb, the coupling member CTPb may be readily replaced. Accordingly, maintenance of the nozzle NZb may be readily performed.

The heat transfer coefficient of the spray part EXPb may be greater than the heat transfer coefficient of the body part BDPb and the coupling member CTPb. In case that the deposition material is heated to be evaporated (or vaporized), the thermal expansion amount of the spray part EXPb may be greater than the thermal expansion amounts of the body part BDPb and the coupling member CTPb. The spray part EXPb may be expanded within the spray hole FSH. Accordingly, the space between an outer surface of the spray part EXPb and an inner surface of the coupling member CTPb may be sealed. Therefore, the deposition material may not leak into the space between the outer surface of the spray part EXPb and the inner surface of the coupling member CTPb, and may be sprayed to the outside through the hole HL, thereby reducing unnecessary loss.

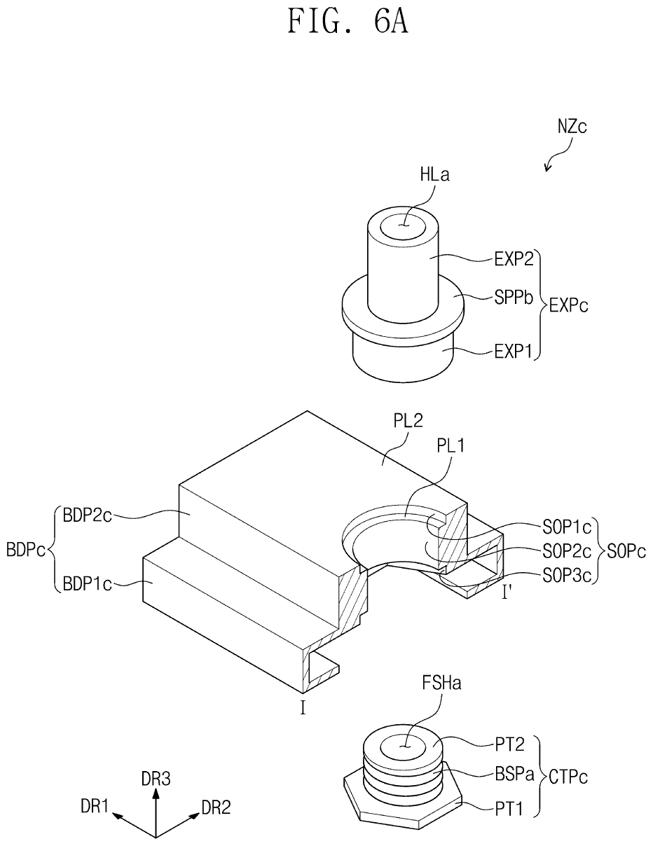

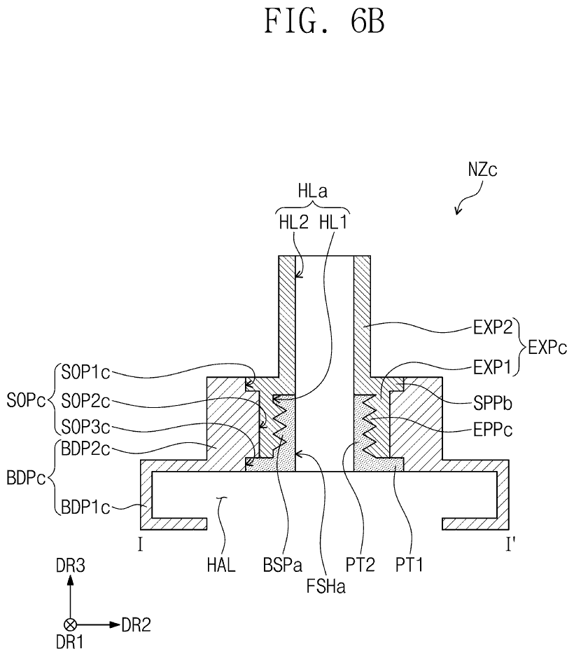

FIGS. 6A and 6B are schematic diagrams illustrating a nozzle according to another embodiment.

For convenience of explanation, in FIG. 6A, a body part BDPc is illustrated in a cross-sectional view taken along line I-I′, and a spray part EXPc and a coupling member CTPc are illustrated in a perspective view.

FIG. 6A illustrates a state in which the body part BDPc, the spray part EXPc, and the coupling member CTPc are separated from each other, and FIG. 6B illustrates a state in which the body part BDPc, the spray part EXPc, and the coupling member CTPc are coupled to each other.

Referring to FIG. 6A, upper surfaces PL1 and PL2 of the body part BDPc may include a first surface PL1 and a second surface PL2. The first surface PL1 may be adjacent to a coupling opening SOPc. The second surface PL2 may be spaced apart from the coupling opening SOPc. The first surface PL1 and the second surface PL2 may be connected to form a stepped portion. The height of the first surface PL1 may be lower than the height of the second surface PL2.

The coupling opening SOPc may include a first coupling opening SOP1c, a second coupling opening SOP2c, and a third coupling opening SOP3c. The first coupling opening SOP1c may be defined by the second surface PL2. The second coupling opening SOP2c may be defined by an inner surface of a second body part BDP2c. The third coupling opening SOP3c may be defined by a first body part BDP1c. For example, the first coupling opening SOP1c, the second coupling opening SOP2c, and the third coupling opening SOP3c may be integral with each other.

For example, the maximum diameter of the first coupling opening SOP1c may be greater than the maximum diameter of the second coupling opening SOP2c. For example, the third coupling opening SOP3c may have a polygonal shape, e.g., in plan view. An inner surface of the first body part BDP1c defining the third coupling opening SOP3c may include flat surfaces arranged at a certain angle.

The coupling member CTPc may include a first portion PT1, a second portion PT2, and spray protrusions BSPa. The second portion PT2 may be disposed on the first portion PT1. The second portion PT2 may extend from the first portion PT1 in the third direction DR3. For example, the first portion PT1 and the second portion PT2 may be integral with each other.

In plan view, an upper surface of the first portion PT1 may have a polygonal shape. The first portion PT1 may have a polygonal column shape. For example, in FIG. 6A, the first portion PT1 is illustrated to have a hexagonal column shape. The second portion PT2 may have a cylindrical shape. The maximum length of the first portion PT1 in the first direction DR1 may be greater than the diameter of the second portion PT2. In plan view, the thickness of the first portion PT1 in the third direction DR3 may be smaller than the thickness of the second portion PT2 in the third direction DR3.

The spray protrusions BSPa may be disposed on an outer surface of the second portion PT2. The spray protrusions BSPa may have a shape surrounding the second portion PT2.

The spray part EXPc may include a first spray part EXP1, a second spray part EXP2, and a support part SPPb. The second spray part EXP2 may be disposed on the first spray part EXP1. The support part SPPb may be disposed between the first spray part EXP1 and the second spray part EXP2. For example, the first spray part EXP1, the second spray part EXP2, and the support part SPPb may be integral with each other.

For example, the first spray part EXP1 and the second spray part EXP2 may have a cylindrical shape. The support part SPPb may have an annular shape. The diameter of the first spray part EXP1 may be greater than the diameter of the second spray part EXP2. The diameter of the support part SPPb may be greater than the diameter of the first spray part EXP1.

Referring to FIGS. 6A and 6B, a hole HLa may be defined (or formed) in the spray part EXPc. The hole HLa may extend in the third direction DR3. The hole HLa may include a first hole HL1 and a second hole HL2. The first hole HL1 may be defined by (or formed in) the first spray part EXP1. The second hole HL2 may be defined by (or formed in) the second spray part EXP2. In case that viewed from the first direction DR1, the diameter of the first hole HL1 in the second direction DR2 may be greater than the diameter of the second hole HL2 in the second direction DR2.

The spray part EXPc may include coupling protrusions EPPb. The coupling protrusions EPPb may be disposed on an inner surface of the first spray part EXP1 defining the first hole HL1. The coupling protrusions EPPb may be disposed to correspond to the spray protrusions BSPa of the coupling member CTPc.

The spray part EXPc, the body part BDPc, and the coupling member CTPc may be coupled to each other. For example, the coupling member CTPc may be disposed in the coupling opening SOPc of the body part BDPc. The first portion PT1 of the coupling member CTPc may be disposed in the third coupling opening SOP3c. The second portion PT2 may be disposed in the second coupling opening SOP2c.

The spray part EXPc may disposed (or inserted) in the coupling opening SOPc. The first spray part EXP1 may disposed (or inserted) in the second coupling opening SOP2c. The first spray part EXP1 may be disposed on the first portion PT1 of the coupling member CTPc.

The first spray part EXP1 may be coupled to the second portion PT2 of the coupling member CTPc. The coupling protrusions EPPb disposed on an outer surface of the first spray part EXP1 may be coupled to the spray protrusions BSPa disposed on an outer surface of the second portion PT2 in an engaged manner. Accordingly, the spray part EXPc may be coupled to the coupling member CTPc. The spray part EXPc may be coupled to the body part BDPc by the coupling member CTPc.

The support part SPPb may be disposed in the first coupling opening SOP1c. The second spray part EXP2 may be exposed to the outside from the body part BDPc. The second hole HL2 may overlap a spray hole FSHa. The deposition material accommodated in the crucible CRB (see FIG. 1) may be vaporized (or evaporated) and sprayed to the outside from the second hole HL2, after passing through the connection groove HAL and the spray hole FSHa.

The possibility of occurrence of wear on an inner surface of the body part BDPc may be reduced in a case where the spray part EXPc is coupled to the body part BDPc by the coupling member CTPc, compared to a case where the spray part EXPc and the body part BDPc are directly coupled to each other.

For example, the coupling member CTPc is coupled to be detachable from the body part BDPc, so that the coupling member CTPc may be readily replaced. Accordingly, maintenance of the nozzle NZc may be readily performed.

The coefficient of thermal expansion of the spray part EXPc may be greater than the coefficients of thermal expansion of the body part BDPc and the coupling member CTPc. In case that the deposition material is heated to be evaporated (or vaporized), the thermal expansion amount of the spray part EXPc may be greater than the thermal expansion amounts of the body part BDPc and the coupling member CTPc. The spray part EXPc may expand within the coupling opening SOPc. Accordingly, the space between an inner surface of the body part BDPc and an outer surface of the spray part EXPc may be sealed. Therefore, the deposition material may not leak into the space between the outer surface of the spray part EXPc and the inner surface of the coupling member CTPc, and may be sprayed to the outside through the hole HLa, thereby reducing unnecessary loss.

FIGS. 7A and 7B are schematic diagrams illustrating a spray part according to another embodiment.

For example, FIGS. 7A and 7B are illustrated in perspective views.

Since coupling protrusions EPP and a hole HL of FIGS. 7A and 7B are the same as the coupling protrusions EPP and the hole HL of FIGS. 3A and 3B, a description thereof will be omitted or simplified for descriptive convenience.

Referring to FIG. 7A, fastening grooves FLG may be defined (or formed) in an outer surface of the spray part EXPd. As the fastening grooves are defined, flat surfaces FLA may be disposed on an outer surface of the spray part EXPd.

For example, in case that the spray part EXPd is coupled to the body part BDP (see FIG. 2), the fastening grooves FLG are defined (or formed) in the outer surface of the spray part EXPd, thus the spray part EXPd may be readily used by a tool. Accordingly, in case that the spray part EXPd is coupled to the body part BDP (see FIG. 2), the coupling process may be readily performed.

Referring to FIG. 7B, the spray part EXPe may have a hexagonal column shape. In plan view, an upper surface of the spray part EXPe may have a hexagonal shape. However, this is illustrated as an example, and the shape of the spray part EXPe may have a different polygonal shape.

Flat surfaces FLAa may be disposed on the outer surface of the spray part EXPe. For example, as the planes FLAa is disposed on the outer surface of the spray part EXPe, a tool may be readily facilitated during coupling of the spray part EXPe to the body part BDP (see FIG. 2). Accordingly, in case that the spray part EXPe is coupled to the body part BDP (see FIG. 2), the coupling process may be readily performed.

FIG. 8 is a schematic plan view of a display panel manufactured using the deposition apparatus illustrated in FIG. 1.

Referring to FIG. 8, the display panel DP may have a rectangular shape with short sides extending in the first direction DR1 and long sides extending in the second direction DR2, but the shape of the display panel DP is not limited thereto. The display panel DP may include a display unit DA and a non-display unit NDA surrounding the display unit DA.

The display panel DP may be a light emitting type display panel. The display panel DP may be an organic light emitting display panel or a quantum dot light emitting display panel. The light emitting layer of the organic light emitting display panel may include an organic light emitting material. The light emitting layer of the quantum dot light emitting display panel may include such as quantum dots and quantum rods. Hereinafter, the display panel DP will be described as an organic light emitting display panel.

The display panel DP may include pixels PX, scan lines SL1-SLm, data lines DL1-DLn, light emitting lines EL1-ELm, first and second control lines CSL1 and CSL2, first and second power lines P1 and P2, connection lines CNL, and pads PD. Here, m and n may be natural numbers.

The pixels PX may be disposed in the display unit DA. A scanning driving unit SDV and a light emitting driving unit EDV may be disposed in the non-display unit NDA adjacent to the long sides of the display panel DP. A data driving unit DDV may be disposed in the non-display unit NDA adjacent to one of the short sides of the display panel DP. In plan view, the data driving unit DDV may be adjacent to a lower end portion of the display DP.

The scan lines SL1-SLm may extend in the first direction DR1 to be connected to the pixels PX and the scanning driving unit SDV. The data lines DL1-DLn may extend in the second direction DR2 to be connected to the pixels PX and the data driving unit DDV. The light emitting lines EL1-ELm may extend in the first direction DR1 to be connected to the pixels PX and the light emitting driving unit EDV.

The first power line P1 may extend in the second direction DR2 and may be disposed in the non-display unit NDA. The first power lines P1 may be disposed between the display unit DA and the light emitting driving unit EDV. However, embodiments are not limited thereto, and the first power line P1 may be disposed between the display unit DA and the scanning driving unit SDV.

The connection lines CNL may extend in the first direction DR1 and may be arranged in the second direction DR2. The connection lines CNL may be connected to the first power lines P1 and the pixels. A first voltage may be applied to the pixels PX through the first power lines P1 and the connection lines CNL connected to each other.

The second power line P2 may be disposed in the non-display unit NDA. The second power lines P2 may expend along the long sides of the display panel DP and one of the sides of the display panel in which the data driving unit DDV is not disposed. The second power lines P2 may be disposed outside the scanning driving unit SDV and the light emitting driving unit EDV.

For example, the second power line P2 may extend toward the display unit DA and may be connected to the pixels PX. A second voltage having a voltage level lower than the first voltage may be applied to the pixels PX through the second power lines P2.

The first control line CSL1 may be connected to the scanning driving unit SDV, and may extend toward the lower end portion of the display panel DP in plan view. The second control line CSL2 may be connected to the light emitting driving unit EDV, and may extend toward the lower end portion of the display panel DP in plan view. The data driving unit DDV may be disposed between the first control line CSL1 and the second control lines CSL2.

The pads PD may be disposed on the display panel DP. The pads PD may be more adjacent to the lower end portion of the display panel DP than the data driving unit DDV. The data driving unit DDV, the first power line P1, the second power line P2, the first control line CSL1, and the second control line CSL2 may be connected to the pads PD. The data lines DL1-DLn may be connected to the data driving unit DDV, and the data driving unit DDV may be connected to the pads PD corresponding to the data lines DL1-DLn.

The cell regions CEA illustrated in FIG. 1 may correspond to the display panel DP illustrated in FIG. 8. The display panel DP may be disposed on one cell region CEA, and the light emitting elements of a single display panel DP may be formed by the cell openings MOP defined (or formed) in the cell regions CEA.

Unit regions corresponding to the display panel DP may be defined (or formed) in the above-described substrate SUB (see FIG. 1). After the light emitting elements are formed in the unit regions, the unit regions may be cut. Accordingly, the display panel DP shown in FIG. 8 may be manufactured.

For example, a timing controller for controlling the operations of the scanning driving unit SDV, the data driving unit DDV, and the light emitting driving unit EDV, and a voltage generator for generating the first and the second voltages may be disposed on a printed circuit board. The timing controller and the voltage generator may be connected to the corresponding pads PD through the printed circuit board.

The scanning driving unit SDV may generate scanning signals, and the scan signals may be applied to the pixels PX through the scan lines SL1-SLm. The data driving unit DDV may generate data voltages, and the data voltages may be applied to the pixels PX through the data lines DL1-DLn. The light emitting driving unit EDV may generate light emitting signals, and the light emitting signals may be applied to the pixels PX through the light emitting lines EL1-ELm.

The pixels PX may receive data voltages in response to scanning signals. The pixels PX may display an image by emitting light having a luminance corresponding to the data voltages in response to the light emitting signals. The light emitting time of the pixels PX may be controlled by light emitting signals.

The above-described wires may include the data lines DL1-DLn. Pads connected to the above-described wires may include the pads PD illustrated in FIG. 8. The display panel DP, in which the light emitting layers of the pixels PX are not formed, may be defined as the above-described substrate SUB.

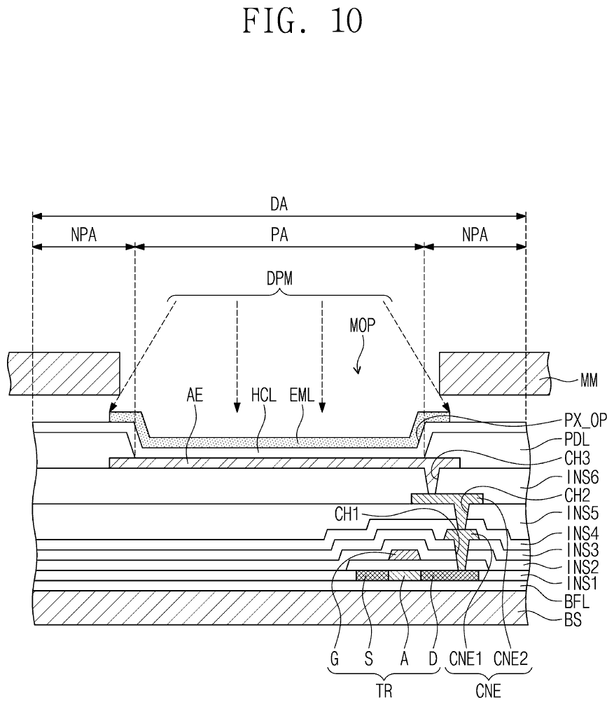

Hereinafter, a cross-sectional structure of the substrate SUB, in which the light emitting layers are not formed, will be described in FIG. 10. The pads PD may be formed on the substrate SUB, and the substrate SUB may be defined (or formed) in a state in which the printed circuit board is not connected. The pads PD may be connected to a ground terminal, and thus the pads PD and the data lines DL1-DLn may be grounded.

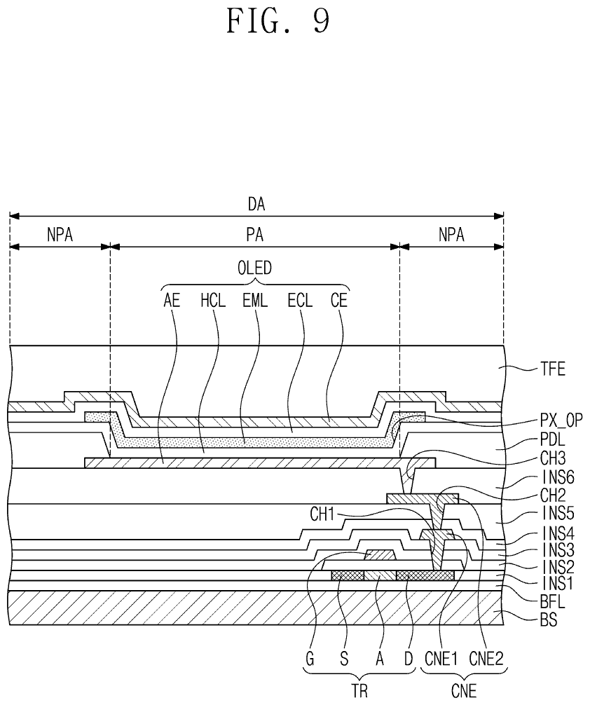

FIG. 9 is a schematic diagram illustrating a cross-section of a pixel illustrated in FIG. 8.

Referring to FIGS. 8 and 9, the pixels PX may be disposed on the base substrate BS and may include a transistor TR and a light emitting element OLED. The transistors TR and the light emitting elements OLED of the pixels PX may be connected to the data lines DL1-DLn and the first and second power lines P1 and P2.

The transistors TR and the light emitting elements OLED of the pixels PX may be connected to the pads PD of FIG. 7 through the data lines DL1-DLn (see FIG. 7) and the first and second power lines P1 and P2 (see FIG. 7). The transistors TR of the pixels PX may be connected to the pads PD of FIG. 7 through the data lines DL1-DLn (see FIG. 7).

The light emitting elements OLED may include a first electrode AE, a second electrode CE, a hole control layer HCL, an electron control layer ECL, and an emitting layer EML. The first electrode AE may be an anode electrode, and the second electrode CE may be a cathode electrode.

The transistor TR and the light emitting elements OLED may be disposed on the base substrate BS. For example, a single transistor TR is illustrated, but substantially the pixel PX may include a plurality of transistors and at least one capacitor for driving the light emitting elements OLED.

The display unit DA may include a light emitting unit PA corresponding to the pixel PX and a non-light emitting unit NPA around the light emitting unit PA. The light emitting elements OLED may be disposed on the light emitting unit PA.

The base substrate BS may include a flexible plastic substrate. For example, the base substrate BS may include a transparent polyimide (P1). A buffer layer BFL may be disposed on the base on the base substrate BS, and the buffer layer BFL may be an inorganic layer.

A semiconductor pattern may be disposed on the buffer layer BFL. The semiconductor pattern may include polysilicon. However, embodiments are not limited thereto, and the semiconductor pattern may include amorphous silicon or metal oxide.

The semiconductor pattern may be doped with an N-type dopant or a P-type dopant. The semiconductor pattern may include a heavily doped region and a lightly doped region. The conductivity of the heavily doped region may be greater than the lightly doped region, and may substantially function as a source electrode and a drain electrode of the transistor TR. The lightly doped region may substantially correspond to an active region (or channel) of the transistor.

A source region S, an active region A, and a drain region D may be formed from the semiconductor pattern. A first insulating layer INS1 may be disposed on the semiconductor pattern. A gate electrode G of the transistor TR may be disposed on the first insulating layer INS1. A second insulating layer INS2 may be disposed on the gate electrode G. A third insulating layer INS3 may be disposed on the second insulating layer INS2.

A connecting electrode CNE may be disposed between the transistor TR and the light emitting element OLED to connect the transistor TR and the light emitting element OLED. The connecting electrode CNE may include a first connecting electrode CNE1 and a second connecting electrode CNE2.

The first connecting electrode CNE1 may be disposed on the third insulating layer INS3 and connected to the drain region D through a first contact hole CH1 defined (or formed) in the first to third insulating layers INS1 to INS3. A fourth insulating layer INS4 may be disposed on the first connecting electrode CNE1. A fifth insulating layer INS5 may be disposed on the fourth insulating layer INS4.

The second connecting electrode CNE2 may be disposed on the fifth insulating layer INS5. The second connecting electrode CNE2 may be connected to the first connecting electrode CNE1 through a second contact hole CH2 defined (or formed) in the fifth insulating layer INS5. A sixth insulating layer INS6 may be disposed on the second connecting electrode CNE2. The first to sixth insulating layers INS1 to INS6 may be an inorganic layer or an organic layer.

The first electrode AE may be disposed on the sixth insulating layer INS6. The first electrode AE may be connected to the second connecting electrode CNE2 through a third contact hole CH3 defined (or formed) in the sixth insulating layer INS6. A pixel-defining film PDL exposing a certain portion of the first electrode AE may be disposed on the first electrode AE and the sixth insulating layer INS6. An opening PX_OP for exposing a certain portion of the first electrode AE may be defined (or formed) in the pixel-defining film PDL.

The hole control layer HCL may be disposed on the first electrode AE and the pixel-defining film PDL. The hole control layer HCL may be disposed in common on the light emitting unit PA and the non-light emitting unit NPA. The hole control layer HCL may include a hole transport layer and a hole injection layer.

The emitting layer EML may be disposed on the hole control layer HCL. The emitting layer EML may be disposed in a region corresponding to the opening PX_OP. The emitting layer EML may include an organic material and/or an inorganic material. The emitting layer EML may generate any one of red light, green light, and blue light.

The electron control layer ECL may be disposed on the emitting layer EML and the hole control layer HCL. The electron control layer ECL may be disposed in common on the light emitting unit PA and the non-light emitting unit NPA. The electron control layer ECL may include an electron transport layer and an electron injection layer.

The second electrode CE may be disposed on the emitting layer EML and the hole control layer HCL. The second electrode CE may be disposed in common over the pixels PX. A layer from the buffer layer BFL to the light emitting elements OLED may be defined as a pixel layer PXL.

A thin-film encapsulating layer TFE may be disposed on the light emitting elements OLED. The thin-film encapsulating layer TFE may be disposed on the second electrode CE to cover the pixel PX. The thin-film encapsulating layer TFE may include at least two inorganic layers and an organic layer between the at least two inorganic layers. The inorganic layer may protect the pixel PX from moisture/oxygen. The organic layer may protect the pixel PX from foreign substances such as dust particles.

The first voltage may be applied to the first electrode AE through the transistor TR, and the second voltage having a lower voltage level than the first voltage may be applied to the second electrode CE. Holes and electrons injected into the emitting layer EML may combine to generate excitons, and the light emitting elements OLED may emit light in case that the excitons transition to the bottom state.

FIG. 10 is a schematic diagram illustrating a deposition process for the light emitting element illustrated in FIG. 9.

For convenience of description, the substrate SUB and masks MM illustrated in FIG. 1 are vertically reversed in FIG. 10.

Referring to FIGS. 1 and 10, a layer from the base substrate BS to the layer disposed the first electrode AE may be defined as the substrate SUB. The masks MM may be disposed on the substrate SUB.

As described above, the transistor TR may be connected to the pads PD through the data lines DL1-DLn. For example, the substrate SUB may include the data lines DL1-DLn defined by the above-described lines and the pads PD connected to the data lines DL1-DLn.

The masks MM may be disposed to face the substrate SUB. The masks MM may be disposed to be close to the substrate SUB. A deposition material DPM may be provided (or sprayed) onto the substrate SUB through the cell opening MOP defined (or formed) in upper surfaces of the masks MM. The emitting layer EML may be formed on the substrate SUB by the deposition material DPM.

According to an embodiment, the spray part EXP including a material different from materials of the body part BPD of the nozzle NZ may be separated and replaced. The body part BPD and the crucible CRB may include a same material. Accordingly, in case that the nozzle NZ is heated at high temperature, a difference of the thermal expansion amount may occur in the body part BPD and the spray part EXP. The spray part EXP having a high thermal expansion coefficient may expand to seal the space between the body part BPD and the spray part EXP.

According to an embodiment, the body part BPD and the spray part EXP may be coupled to each other by the coupling member CTPa, CTPb, or CTPc. The coupling member CTPa, CTPb, or CTPc may be coupled to the body part BPD, and the spray part EXP may be coupled to the coupling member CTPa, CTPb, or CTPc. Accordingly, wear generated in case that the spray part EXP is directly coupled to the body part BPD may not occur in the body part BPD, so that maintenance and repair of the nozzle NZ may be readily performed.

For example, flat surfaces may be disposed on the outer surface of the spray part EXP. Accordingly, in case that the spray part EXP is coupled to the body part BPD, the fastening strength between the spray part EXP and the body part BPD may be precisely adjusted using a tool.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A deposition apparatus comprising:
a mask frame;
a mask disposed on the mask frame;
a crucible disposed below the mask frame; and
a nozzle disposed between the crucible and the mask frame and coupled to the crucible, wherein
the nozzle includes:
a body part including a coupling opening, and
a spray part disposed in the coupling opening and including a hole overlapping the coupling opening, and
a thermal expansion coefficient of the spray part is greater than a thermal expansion coefficient of the body part.

2. The deposition apparatus of claim 1, wherein
the crucible and the body part comprise a same material, and
the spray part comprises a material different from materials of the crucible and the body part.

3. The deposition apparatus of claim 1, wherein
the body part further comprises body protrusions disposed in the coupling opening and disposed on an inner surface of the body part,
the spray part further comprises coupling protrusions disposed on an outer surface of the spray part,
the body protrusions and the coupling protrusions are coupled to each other, and
the body part and the spray part are coupled to each other in an engaged manner by the body protrusions and the coupling protrusions.

4. The deposition apparatus of claim 1, wherein
the nozzle further comprises a coupling member disposed in the coupling opening and including a spray hole, and
the body part and the spray part are coupled to each other by the coupling member.

5. The deposition apparatus of claim 4, wherein a thermal expansion coefficient of the coupling member is smaller than the thermal expansion coefficient of the spray part.

6. The deposition apparatus of claim 4, wherein the coupling opening of the body part comprises:
a first coupling opening adjacent to an upper surface of the body part; and
a second coupling opening disposed below the first coupling opening and having a diameter larger than a diameter of the first coupling opening.

7. The deposition apparatus of claim 6, wherein
the coupling member comprises first spray protrusions disposed on an inner surface of the coupling member and disposed in the spray hole,
the spray part comprises coupling protrusions disposed on an outer surface of the spray part,
the coupling member is disposed in the second coupling opening of the body part, and
the coupling protrusions are coupled to the first spray protrusions in an engaged manner such that the spray part and the coupling member are coupled to each other.

8. The deposition apparatus of claim 7, wherein the coupling member further comprises second spray protrusions disposed on an outer surface of the coupling member.

9. The deposition apparatus of claim 8, wherein the body part comprises body protrusions disposed on an inner surface of the body part and disposed in the second coupling opening, and
the body protrusions are coupled to the second spray protrusions of the coupling member in an engaged manner such that the body part and the coupling member are coupled to each other.

10. The deposition apparatus of claim 4, wherein
the coupling opening of the body part comprises:
a first coupling opening adjacent to an upper surface of the body part;
a second coupling opening disposed below the first coupling opening; and
a third coupling opening disposed below the second coupling opening,
the first coupling opening has a larger diameter than the second coupling opening, and
the third coupling opening has a larger diameter than the second coupling opening.

11. The deposition apparatus of claim 10, wherein
the coupling member comprises:
a first part having a cylindrical shape;
a second part disposed on the first part and having, in plan, a cylindrical shape having a diameter smaller than a diameter of the first part; and
a spray protrusion disposed on an outer surface of the second part,
the first part is disposed in the first coupling opening of the body part, and
the second part is disposed in the second coupling opening of the body part.

12. The deposition apparatus of claim 11, wherein
the spray part comprises:
a first spray part having a cylindrical shape;
a second spray part disposed on the first spray part and having, in plan view, a cylindrical shape having a diameter smaller than a diameter of the first spray part; and
a coupling protrusion disposed on an inner surface of the first spray part and disposed in the hole of the spray part, and
the coupling protrusion is coupled to the spray protrusion of the coupling member in an engaged manner within the second coupling opening such that the spray part and the coupling member are coupled to each other.

13. The deposition apparatus of claim 12, wherein
the spray part further comprises a support part disposed between the first spray part and the second spray part and having a ring shape, and
the support part is disposed in the third coupling opening of the body part.

14. The deposition apparatus of claim 1, wherein
an upper surface of the spray part has a ring shape in plan view, and
a plurality of fastening grooves are formed in an outer surface of the spray part.

15. The deposition apparatus of claim 1, wherein
an upper surface of the spray part has a polygonal shape in plan view, and
an outer surface of the spray part comprises a plurality of flat surfaces.

16. A deposition apparatus comprising:
a mask frame;
a mask disposed on the mask frame;
a crucible disposed below the mask frame; and
a nozzle disposed between the crucible and the mask frame; and
wherein the nozzle includes:
a body part including a coupling opening,
a spray part disposed in the coupling opening and including a hole overlapping the coupling opening, and
a coupling member disposed between the body part and the spray part, and including a spray hole, and
the body part and the spray part are coupled to each other by the coupling member.

17. The deposition apparatus of claim 16, wherein
the spray part comprises a coupling protrusion disposed on an outer surface of the spray part,
the coupling member comprises a first spray protrusion disposed on an inner surface of the coupling member and disposed in the spray hole, and
the first spray protrusion and the coupling protrusion are coupled to each other in an engaged manner.

18. The deposition apparatus of claim 17, wherein
the body part comprises a body protrusion disposed on an inner surface of the body part and disposed in the coupling opening,
the coupling member further comprises a second spray protrusion disposed on an outer surface of the coupling member, and
the second spray protrusion and the body protrusion are coupled to each other in an engaged manner.

19. The deposition apparatus of claim 16, wherein the coupling member comprises:
a first part having a cylindrical shape;
a second part disposed on the first part; and
a spray protrusion disposed on an outer surface of the second part.

20. The deposition apparatus of claim 19, wherein
the spray part comprises a coupling protrusion disposed on an inner surface of the spray part and disposed in the hole of the spray part, and
the coupling protrusion and the spray protrusion are coupled to each other in an engaged manner.
